(19) United States
(12) Patent Application Publication
(10) Pub. No.: US 2026/0354210 A1
(43) Pub. Date: Nov. 5, 2026

(54) MANAGING IMPEDANCE MATCHING IN A CHIP PACKAGE

(71) Applicant: Yangtze Memory Technologies Co., Ltd., Wuhan (CN)

(72) Inventors: Gaoyang YE, Wuhan (CN); Ajuan ZHU, Wuhan (CN); Ting CHEN, Wuhan (CN); Weizhi JIANG, Wuhan (CN)

(21) Appl. No.: 19/427,144

(22) Filed: Dec. 19, 2025

(30) Foreign Application Priority Data
Apr. 30, 2025 (CN) 202510565181.0

(51) Int. Cl. H10W 44/00; H10W 70/00; H10W 70/60; H10W 74/10; H10W 90/00

(52) U.S. Cl. CPC H10W 44/501; H10W 70/099; H10W 74/111; H10W 90/7295; H10W 70/611

(57) ABSTRACT

Systems, devices, and methods for a chip package are provided. In one aspect, a chip package includes a base board and a solder pad positioned at a surface of the base board. The base board includes a transmission line coupled to the solder pad. The transmission line includes a coil structure positioned adjacent to the solder pad, and the coil structure includes a plurality of turns of curved lines wrapped around a central axis.

### CROSS-REFERENCE TO RELATED APPLICATIONS

This application claims priority to Chinese Patent Application No. 202510565181.0, filed on Apr. 30, 2025, which is hereby incorporated by reference in its entirety.

### TECHNICAL FIELD

The present disclosure relates to chip packages and impedance matching for chip packages.

### BACKGROUND

Semiconductor devices may be classified into non-volatile memory devices, such as flash memory devices, and volatile memory devices, such as dynamic random-access memory (DRAM). The semiconductor memory devices can have different structures with different densities of memory cells and lines on a chip. A memory device normally includes a memory array of memory cells and control circuitries. The control circuitries can facilitate operations of the memory array.

A universal flash storage (UFS) package may be used to integrate a memory device with other devices. Ball grid array (BGA) balls can be used as the electrical interface between the UFS chip and a printed circuit board (PCB). The solder balls can be arranged in a grid pattern on the underside of the UFS package, providing high-density interconnects for efficient signal transmission, power delivery and grounding.

### SUMMARY

The present disclosure describes methods, devices, systems and techniques for managing impedance matching in chip packages.

One aspect of the present disclosure features a chip package, including a base board; and a solder pad positioned at a surface of the base board, where the base board includes a transmission line coupled to the solder pad, the transmission line includes a coil structure positioned adjacent to the solder pad, and the coil structure includes a plurality of turns of curved lines wrapped around a central axis.

In some implementations, the coil structure of the transmission line at least partially overlaps with the solder pad.

In some implementations, the coil structure includes a planar spiral coil.

In some implementations, the planar spiral coil includes at least one of a planar square spiral coil, a planar rectangular spiral coil, a planar hexagonal spiral coil, or a planar octagonal spiral coil.

In some implementations, the transmission line includes a routing structure extending from the coil structure, and an impedance of a combination of the coil structure and the solder pad is substantially equal to an impedance of the routing structure.

In some implementations, the solder pad has a capacitance C, the coil structure has an inductance L, and the capacitance C of the solder pad is correlated with the inductance L of the coil structure, satisfying

$${Z}_{0} = \sqrt{\frac{L}{C}} ,$$

where Z₀, is a target impedance.

In some implementations, the coil structure has a uniform pitch between adjacent turns of the plurality of turns of curved lines.

In some implementations, each curved line of the plurality of turns of curved lines has a different perimeter.

In some implementations, the transmission line is configured to transmit a serializer-deserializer (SERDES) signal.

In some implementations, the transmission line is a first transmission line, the base board includes a second transmission line positioned adjacent to the first routing structure, and where the first transmission line is configured to transmit a positive signal, and the second transmission line is configured to transmit a negative signal.

In some implementations, the chip package includes a ball grid array (BGA) package including the base board, and the solder pad is connected to a solder ball.

Another aspect of the present disclosure features a memory device, including: a base board; a solder pad positioned on the base board, where the base board includes: a transmission line coupled to the solder pad, the transmission line includes a coil structure positioned adjacent to the solder pad, and the coil structure includes a plurality of turns of curved lines wrapped around a central axis; and a conductive line; a memory structure including a plurality of memory cells and positioned on the base board; and a control structure including a control circuit and positioned on the base board, where the memory structure is coupled to the control structure through the conductive line of the base board.

In some implementations, the transmission line has a first end coupled to the control structure and a second end coupled to the solder pad, the second end including the coil structure.

In some implementations, the memory device includes a molding encapsulant configured to encapsulate at least the memory structure and the control structure on the base board.

In some implementations, the coil structure of the transmission line at least partially overlaps with the solder pad.

In some implementations, the transmission line includes a routing structure extending from the coil structure, and an impedance of a combination of the coil structure and the solder pad is substantially equal to an impedance of the routing structure.

In some implementations, the solder pad has a capacitance C, the coil structure has an inductance L, and the capacitance C of the solder pad is correlated with the inductance L of the coil structure, satisfying

$${Z}_{0} = \sqrt{\frac{L}{C}} ,$$

where Z₀, is a target impedance.

Another aspect of the present disclosure features a method including: providing a base board; and forming a solder pad at a surface of the base board, where providing the base board includes forming a transmission line, the transmission line includes a coil structure adjacent to the solder pad, and the coil structure includes a plurality of turns of curved lines wrapped around a central axis.

In some implementations, the method includes determining at least one of a length of the coil structure or a number of turns of the plurality of turns of curved lines of the coil structure based on at least a target impedance and a capacitance of the solder pad.

In some implementations, the transmission line includes a routing structure extending from the coil structure. Forming the transmission line includes: forming the transmission line such that an impedance of a combination of the coil structure and the solder pad is substantially equal to an impedance of the routing structure.

In some implementations, the coil structure of the transmission line at least partially overlaps with the solder pad.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1A illustrates a side view of an example of chip package.

FIG. 1B illustrates a side view of an example of base board and solder balls.

FIG. 1C illustrates an enlarged view of a region of the base board of FIG. 1B.

FIG. 2A illustrates a plan view of an example of a chip package.

FIG. 2B illustrates an enlarged view of a pair of solder pads in the chip package of FIG. 2A.

FIG. 3A illustrates a plan view of an example of coil structures of paired transmission lines in a chip package.

FIG. 3B illustrates a cross-sectional view of the chip package along A-A′ axis of FIG. 3A.

FIG. 3C illustrates additional examples of a coil structure of a transmission line. FIG. 4A illustrates an example of an equivalent circuit for a transmission line.

FIG. 4B is a table of an example of dimensionless coefficients for different coil shapes of a coil structure.

FIG. 5A illustrates an example of a time-domain reflectometer (TDR) figure associated with various configurations of transmission lines.

FIG. 5B illustrates an example of an insertion loss figure corresponding to the transmission lines in FIG. 5A.

FIG. 6A illustrates an example of a simulation result of impedance along a reference transmission line without a coil structure.

FIG. 6B illustrates an example of a simulation result of impedance along an example of a transmission line with a coil structure.

FIG. 7 illustrates a flow chart of a process of an example method of forming a chip package.

FIG. 8 illustrates a block diagram of a system having one or more semiconductor devices.

It is to be understood that the various exemplary implementations shown in the figures are merely illustrative representations and are not necessarily drawn to scale.

### DETAILED DESCRIPTION

In semiconductor manufacturing, chip packaging is a step in the semiconductor device fabrication that can encapsulate one or more semiconductor dies of integrated circuits in a supporting case that prevents physical damage, corrosion and the like. The supporting case with the encapsulated semiconductor die(s) can be referred to as a chip package. Impedance matching in a chip package can be important for ensuring good signal integrity and reliable data transmission. In high-speed (e.g., greater than 1 Gbps) electronic systems, mismatched impedance between components can cause signal reflections, leading to data loss, increased error rates and reduced performance. In some examples, the chip package can with a ball grid array (BGA) package with solder balls attached to corresponding solder pads of the BGA package. The solder pads may have large capacitance that may affect the impedance near the solder pads. Additionally, as the transmission speed of the chip package increases in the future, the capacitive effect of the solder pads on impedance matching can become more severe. This makes the impedance matching near the solder pads more challenging.

Implementations of the present disclosure provide a chip package and/or a memory device, and methods to form such chip package. In some implementations, a chip package includes a base board and a solder pad positioned at a surface of the base board. The base board includes a transmission line coupled to the solder pad. The transmission line includes a coil structure positioned adjacent to the solder pad, and the coil structure includes a plurality of turns of curved lines wrapped around a central axis.

Implementations of the present disclosure can provide one or more of the following technical advantages and/or benefits. First, the techniques described in the present disclosure can improve impedance matching near the solder pads. For example, in some implementations, a transmission line in a chip package includes a coil structure at one end, and the coil structure is positioned adjacent to the solder pad. The coil structure can provide a high inductance, thereby counteracting the impact of the high capacitance of the solder pad on the impedance. Therefore, the overall impedance of the combined structure of the coil structure and the solder pad can be adjusted to match other segments of the transmission line, thereby improving impedance matching. Additionally, the techniques can offer flexibility to determine geometric parameters of the coil structure (e.g., an inner diameter, an outer diameter, a width of the coil structure, a number of turns, and/or a filling ratio of the coil structure) to match a characteristic impedance. The characteristic impedance can be the impedance of another segment of the transmission line (e.g., a routing structure), source/load impedance, or any other relevant impedance. The geometric parameters of the coil structure can be configured to ensure a substantially uniform impedance along the transmission line. Improved impedance matching can reduce signal reflections and insertion loss along the transmission line, thereby enhancing signal integrity.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory cell types, such as SLC (single-level cell), MLC (multi-level cell) like 2-level cells, TLC (triple-level cell), QLC (quad-level cell), or PLC (penta-level cell). Additionally or alternatively, the techniques can be applied to various types of devices and systems, such as secure digital (SD) cards, embedded multimedia cards (eMMC), solid-state drives (SSDs), or universal flash storage (UFS), embedded systems, among others.

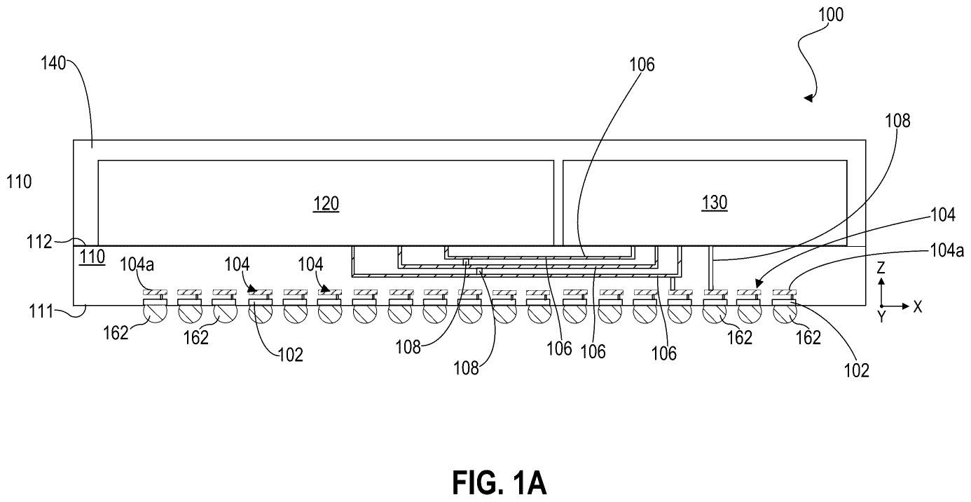

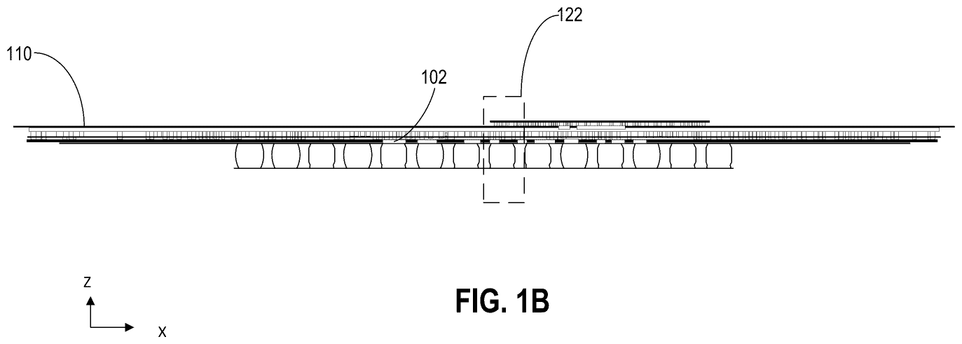

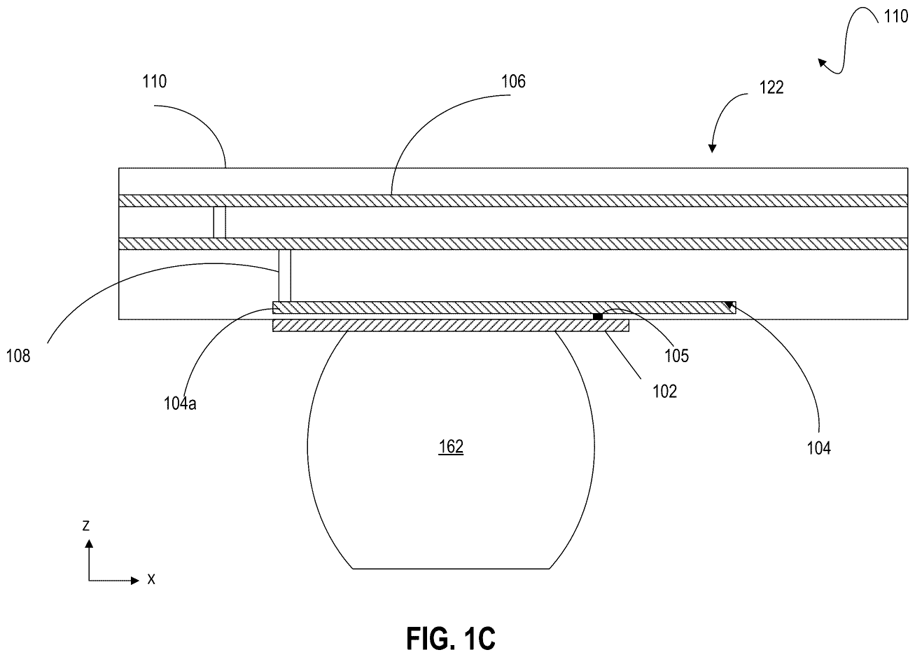

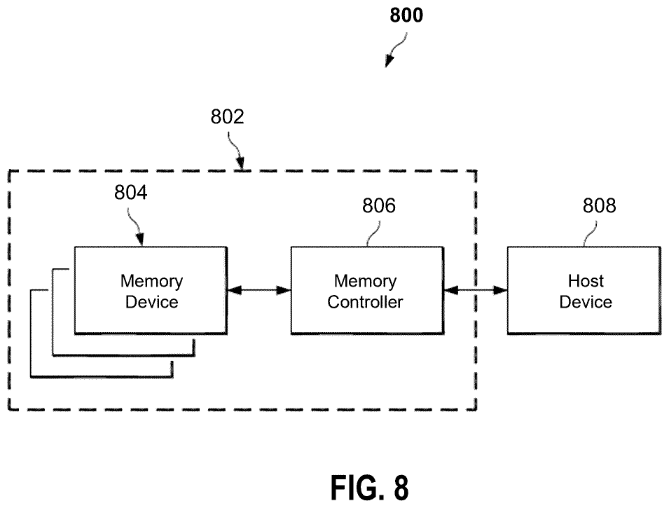

FIG. 1A illustrates a side view of an example of chip package 100, according to one or more implementations of the present disclosure. FIG. 1B illustrates a side view of an example of base board and solder balls, according to one or more implementations of the present disclosure. FIG. 1C illustrates an enlarged view of a region 122 of the base board of FIG. 1B. For ease of description, reference will be made to FIGS. 1A-1C when describing the structure of the chip package 100. The chip package 100 may also be referred to as a memory device in the present disclosure. The chip package 100 can be the memory system 802 of FIG. 8.

The chip package 100 can include a base board 110, and a memory structure 120 and a control structure 130 that are positioned on the base board 110. In some implementations, the chip package is a ball grid array (BGA) package based on Universal Flash Storage (UFS) technology. It is to be noted that the techniques described in the present disclosure are also applicable to other types of BGA packages. For example, the techniques described in the present disclosure can apply to a package where multiple chips are stacked vertically, and the multiple chips can be coupled to one another by through-silicon-vias (TSVs). In another example, the techniques can apply to a package where multiple chips are stacked vertically but offset from one another along a lateral direction to expose an edge portion of an underlying chip, and the exposed edge portion of the underlying chip can be used to form conductive lines for coupling to other chips.

The memory structure 120 and control structure 130 can be any suitable chips. The memory structure 120 and control structure 130 can include various components for providing storage, computing and/or processing functionalities. In some examples, the memory structure 120 can be a high bandwidth memory (HBM) device. The control structure 130 can be a processor, a logic die, or a controller. In some implementations, the memory structure 120 can include one or more memory dies that are vertically stacked on one another. Each memory die can include a memory sub-structure and a control sub-structure. The memory sub-structure can include at least one memory array, and each memory array can include a plurality of memory cells. The memory cells can be DRAM memory cells, NAND memory cells, ferroelectric memory cells, or any other suitable memory cells.

The control sub-structure can include peripheral circuits for the memory sub-structure. The peripheral circuits (e.g., control and sensing circuits) can include any suitable digital, analog, and/or mixed-signal circuits used for facilitating the operations of the memory array. For example, the peripheral circuits can include one or more of a page buffer, a decoder (e.g., a row decoder and a column decoder), a sense amplifier, a driver (e.g., a word line driver), an I/O circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in control structure 130 can use CMOS technology, e.g., which can be implemented with logic processes (e.g., technology nodes of 90 nm, 65 nm, 60 nm, 45 nm, 32 nm, 28 nm, etc.).

The chip package 100 can include a molding encapsulant 140 configured to encapsulate at least the memory structure 120 and the control structure 130 on the base board 110. The molding encapsulant 140 can be made of any suitable material, e.g., silica fillers, resin, and the like. In some implementations, the molding encapsulant 140 includes epoxy molding compound (EMC). The molding encapsulant 140 can cover and safeguard the memory structure 120 and the control structure 130, enhance the chip package 100's mechanical strength, and protect against environment factors (e.g., moisture, or dust). Although the molding encapsulant 140 is depicted in FIG. 1A to cover top surfaces of the memory structure 120 and the control structure 130, in some examples, the molding encapsulant 140 can at least partially expose the top surface of the memory structure 120 and/or the control structure 130.

The base board 110 can be made of suitable insulating material (e.g., dielectric material), such as an epoxy based laminate substrate, a resin-based Bismaleimide-Triazine (BT) substrate, and the like. The base board 110 can be relatively rigid to provide mechanical support to the memory structure 120 and control structure 130. The base board 110 has a first surface 111 and a second surface 112 opposite to the first surface 111 along a vertical direction (e.g., Z direction). The memory structure 120 and control structure 130 can be disposed on the second surface 112 of the base board 110, as illustrated in FIG. 1A.

The base board 110 can also provide electrical support for the memory structure 120 and control structure 130. In some implementations, the base board 110 includes one or more layers of conductive lines, such as copper wires, and the like, with the insulating material in between. The conductive lines 106 on the different layers can be connected by vias 108. The conductive lines 106 can provide interconnects from the inputs/outputs of the memory structure 120 and control structure 130 to contact structures 162 (e.g., solder balls) that are formed on the first surface 111 of the chip package 100. The memory structure 120 and control structure 130 can include input/output (I/O) pads (not shown) that are electrically connected to internal memory arrays and/or circuits of the memory structure 120 and control structure 130.

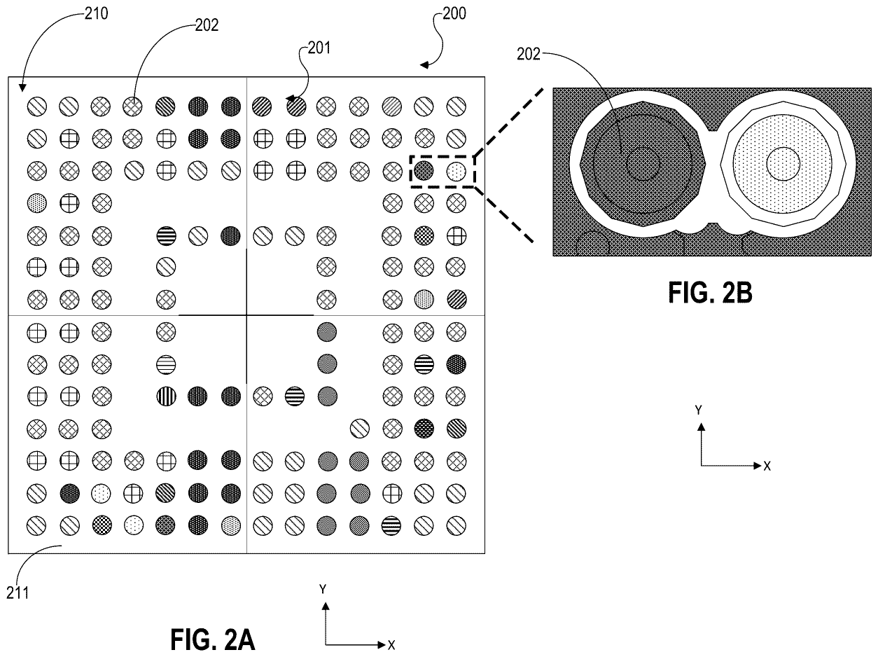

Further, the chip package 100 can include solder pads 102 on the first surface 111 of the chip package 100 to couple to the contact structures 162. The solder pads can include one or more conductive materials, e.g., copper (Cu), nickel (Ni), gold (Au), or any other suitable materials. In some implementations, the chip package 100 is a BGA package (e.g., as illustrated in FIG. 1B and 2A), and each of the contact structures 162 can be a solder ball that is formed on the respective solder pad 102. It is to be noted that, in some examples, the contact structures 162 may not be solder balls. In an example, the chip package 100 is a land grid array (LGA) package, and each of the contact structures 162 can include a solder pad 102 (e.g., a flat contact pad). In another example, the chip package 100 is a pin grid array (PGA) package, and each of the contact structures 162 includes a pin.

The base board 110 can further include a transmission line 104 coupled to the solder pad 102 and the conductive line 106, as illustrated in FIGS. 1A and 1C. The transmission line 104 can include one or more conductive materials, e.g., Cu, or any other suitable materials. A first end 104a of the transmission line 104 can be positioned adjacent to the solder pad 102. A second end (not shown) of the transmission line 104 can extend away from the solder pad 102 (e.g., along Y direction). For example, as illustrated in FIG. 1A, the first end 104a of the transmission line 104 can be positioned directly above the solder pad 102. As used herein, whether one component (e.g., a layer, a structure, or a device) is “on,” “above,” or “below” another component (e.g., a layer, a structure or a device) of a chip package (e.g., the chip package 100) is determined relative to a first surface of a base board of the chip package (e.g., the first surface 111 of the base board 110) in the z-direction (i.e., the vertical direction) when the solder pads on the first surface of the base board face downward, and the memory structure and control structure on the second surface of the base board face upward.

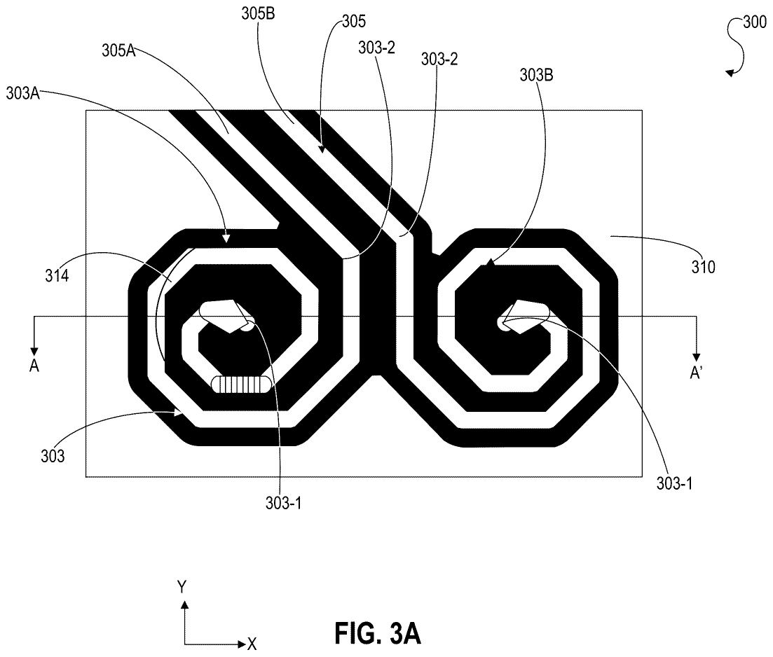

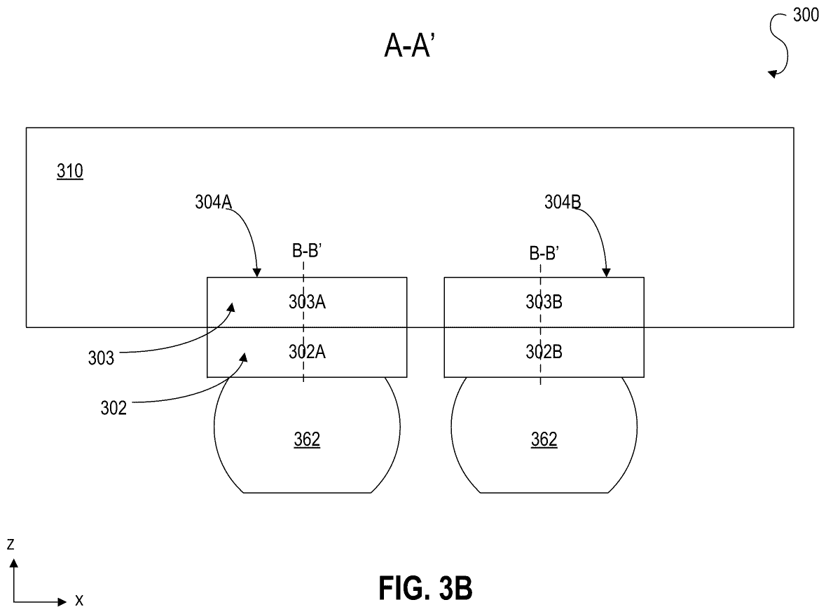

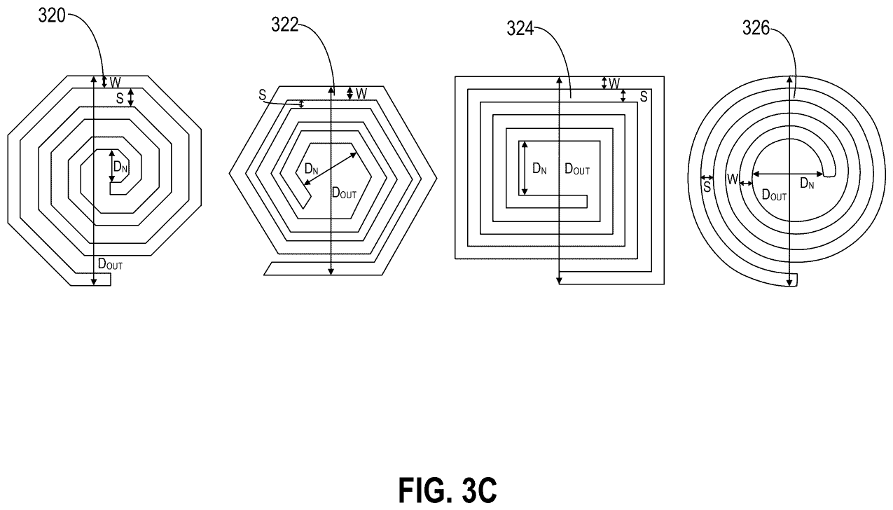

In some examples, as illustrated in FIG. 1C, the first end 104a of the transmission line 104 can be at least partially overlapped with the solder pad 102. As described below in greater details in reference to FIGS. 2A-3B, the first end 104a of the transmission line 104 includes a coil structure.

In some implementations, the transmission line 104 is connected to the solder pad 102 through a vertically extruding portion 105. In some implementations, the vertically extruding portion 105 is part of the transmission line 104. In some implementations, the vertically extruding portion 105 is a via.

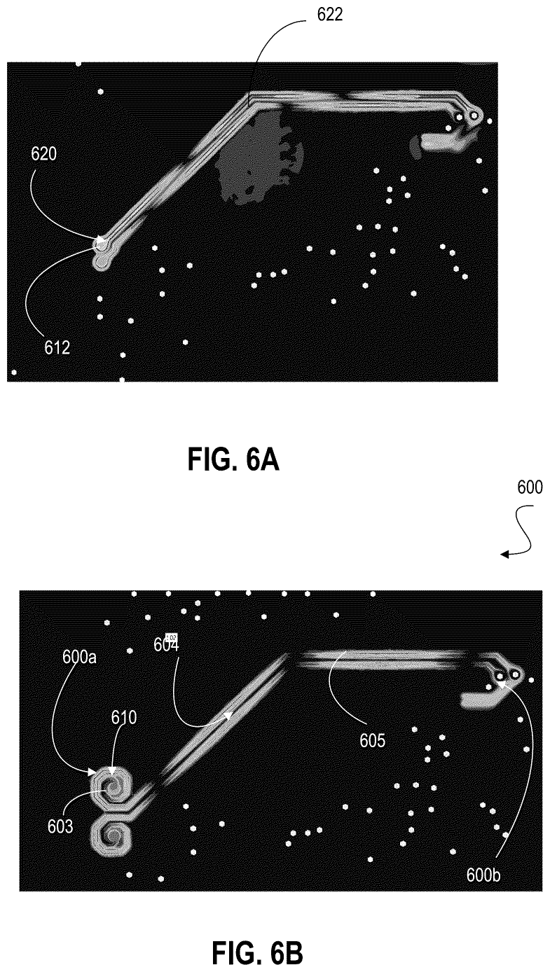

The transmission line 104, the solder pad 102 and the contact structures 162 can be configured to electrically interface the memory structure 120 and/or control structure 130 in the chip package 100 to components out of the chip package 100. In some implementations, the first end 104a of the transmission line 104 is coupled to the solder pad 102, and the second end of the transmission line (e.g., the second end 600b of the transmission line 600 in FIG. 6B) is coupled to the control structure 130. The transmission line 104 can be coupled to the control structure 130 through corresponding vias and/or conductive lines 106. In some implementations, the transmission line 104 is configured to transmit a high-speed signal (e.g., between 1 Gbps and 50 Gbps). For example, the transmission line 104 can be configured to transmit serializer-deserializer (SERDES) signals based on a mobile industry processor interface (MIPI) M-PHY protocol.

FIG. 2A illustrates a plan view of an example of a chip package 200. The chip package 200 can be a BGA package. The chip package 200 can be the memory system 802 of FIG. 8. In the chip package 200, the solder pads 202 can be arranged in a two-dimensional grid pattern 201 across the first surface 211 of the base board 210 of the chip package 200. The grid pattern 201 can include fine-pitch solder pads and/or coarse-pitch solder pads. Fine-pitch solder pads may have smaller distances between them (e.g., 0.8 mm, 0.5 mm, or even finer), allowing for higher component density, while coarse-pitch solder pads may have larger distances between pads (e.g., 1.3 mm or more). In some examples, the grid pattern 201 can include both fine-pitch solder pads and coarse-pitch solder pads based on a specific package design, as illustrated in FIG. 2A. In some examples, the grid pattern 201 can be symmetric to evenly distribute mechanical forces during soldering process.

In some examples, the solder pads 202 in the chip package 200 can be arranged in pairs. Each pair of solder pads 202 includes two solder pads 202 positioned adjacent to each other. FIG. 2B illustrates an enlarged view of a pair of solder pads 202 in the chip package 200 of FIG. 2A. To ensure signal integrity and reduce issues like interference, crosstalk, and/or reflections, a differential signaling technique can be utilized with the chip package 200. A pair of solder pads 202 can be used for two complementary signals (e.g., P and N lanes) for the differential signaling. The paired solder pads 202 (and corresponding contact structures) can be positioned adjacent to each other to help maintain consistent impedance and reduce noise.

The chip package 200 can further include one or more transmission lines (not shown in FIG. 2A) configured to be routed to corresponding solder pads 202 depending on the signal paths. Corresponding to the paired solder pads 202, transmission lines can also be arranged in pairs, with each transmission line coupled to its respective solder pad 202. In some implementations, as described with further details below in reference to FIGS. 3A-3C, the first end of the transmission line that is adjacent to the solder pad 202 can have a coil structure to improve impedance matching.

FIG. 3A illustrate a plan view of an example of coil structures 303 of paired transmission lines 304 in a chip package 300. FIG. 3B illustrates a cross-sectional view of the chip package 300 along A-A′ axis of FIG. 3A. For ease of description, reference will be made to both FIGS. 3A and 3B when describing the structure of the coil structures 303 and the chip package 300.

As illustrated in FIG. 3A, the paired transmission lines 304 can include a first transmission line 304A and a second transmission line 304B. The paired transmission lines 304 can be coupled to the paired solder pads (e.g., paired solder pads 202 of FIG. 2B) for transmitting differential signals. In some implementations, the first transmission line 304A is configured to transmit a positive signal, and the second transmission line 304B is configured to transmit a negative signal.

In some implementations, each of the first transmission line 304A and the second transmission line 304B includes a coil structure 303 and a routing structure 305. The transmission lines 304A, 304B can have the same or substantially similar layout, and the coil structures 303 of the transmission lines 304 can be positioned adjacent to each other in a symmetric manner, as shown in FIG. 3A. In some implementations, the transmission lines 304 are made of copper. It is to be understood that the transmission lines 304 are not necessarily drawn to scale. The routing structures 305 can be longer than they are depicted in FIG. 3A.

In some implementations, the coil structure 303 is positioned adjacent to the solder pad (e.g., solder pads 302 of FIG. 3B), and the coil structure 303 includes a plurality of turns of curved lines 314 wrapped around a central axis. The central axis can be an axis that runs through the center of the coil structure 303, perpendicular to its plane. For example, the center axis can be the axis B-B′ of FIG. 3B. The example implementation shown in FIG. 3A has two curved lines 314 for each coil structure 303. Each curved line 314 of the coil structure 303 can be a thin, narrow conductive trace. Each curved line 314 can include multiple straight segments that are connected in series, as illustrated in FIG. 3A. The curved line 314 can also have a circular shape (e.g., as illustrated in FIG. 3C). In some implementations, the coil structure 303 includes a conductive material, e.g., copper.

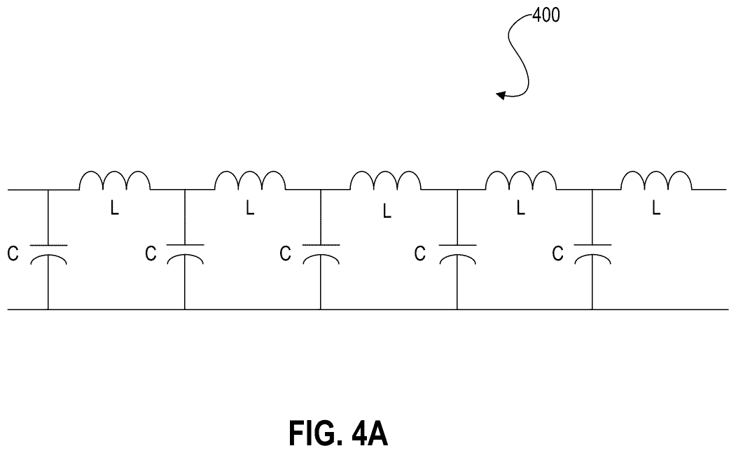

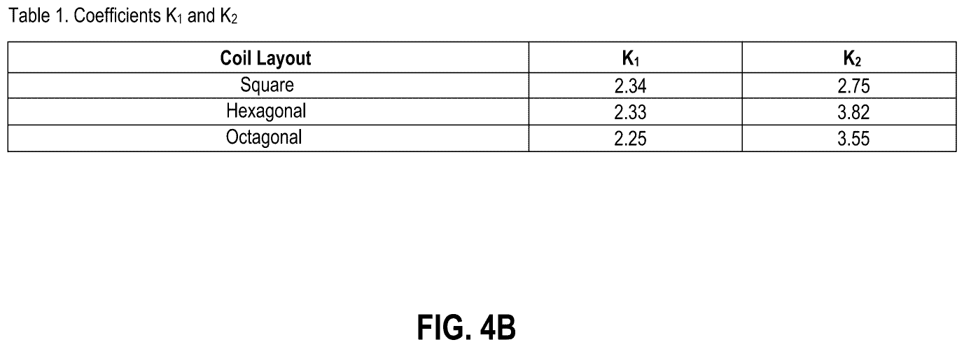

In some implementations, the coil structure 303 has a uniform pitch between adjacent turns of the plurality of turns of curved lines 314. In some implementations, each curved line of the plurality of turns of curved lines 314 has a different perimeter. For example, inner turns can have a smaller perimeter, while outer turns can have a greater perimeter. Geometric parameters of the coil structure 303 (e.g., an inner diameter, an outer diameter, a width of the coil structure 303, a number of turns, and/or a filling ratio of the coil structure 303) can be determined based on a target impedance (e.g., a characteristic impedance) to improve impedance matching along the transmission line 304, as described below in greater details in reference to FIGS. 4A-4B.

In some implementations, the coil structure 303 includes a planar spiral coil. For example, the multiple turns of curved lines 314 can be formed on a single plane, or be single-layered, as shown in FIG. 3A. In some implementations, the coil structure 303 is multi-layered with vias connecting different layers. Each layer in the multi-layered coil structure can include one or more turns of curved lines 314.

One end 303-1 of the coil structure 303 can be terminated at or adjacent to the center axis, while the other end 303-2 of the coil structure 303 can be connected to the corresponding routing structure 305. In some implementations, the routing structure 305 can be an elongated structure that extends away from the coil structure 303. The routing structure 305 can be microstrip, stripline, or coplanar waveguide. The routing structure 305 can be a thin, narrow conductive trace within the base board 310. The width and thickness of the routing structure 305 can be configured to match the characteristic impedance for the signal, and/or to ensure impedance matching along the transmission line 304. In some examples, the routing structure 305 is about a few micrometers to tens of micrometers wide. In some implementations, one end of the routing structure 305 is connected to the coil structure 303, while the other end of the routing structure 305 is coupled to the control structure (e.g., 130 of FIG. 1A). In some implementations, the routing structure 305 is coupled to the control structure (e.g., 130 of FIG. 1A) through conductive line (e.g., 106 of FIG. 1A) and vias (e.g., 108 of FIG. 1A). In some implementations, the routing structure 305 includes the same material as the coil structure 303.

Referring to FIG. 3B, the coil structure 303A, 303B of transmission lines 304 can be positioned adjacent to (e.g., directly above) the solder pads 302A, 302B, respectively. In some implementations, the coil structure 303 of the transmission line 304 is in direct contact with the respective solder pad 302. For example, as shown in FIG. 3B, the coil structure 303A can be in direct contact with the solder pad 302A, while the coil structure 303B can be in direct contact with the solder pad 302B. In some implementations, the coil structure 303 of the transmission line 304 is coupled to the solder pad 302 through vias. For example, briefly turning back to FIG. 1C, the coil structure (e.g., in the first end 104a of the transmission line 104) is coupled to the solder pad 102 through a vertically extruding portion 105 (e.g., a via).

It is to be understood that that FIG. 3B is not necessarily drawn to scale. Although FIG. 3B illustrates that the coil structure 303 and its corresponding solder pad 302 have similar thickness or lateral size, the coil structure 303 and the solder pad 302 can have different thickness (e.g., along Z direction) and/or lateral size (e.g., along X, Y direction). Additionally, although the coil structure 303 is depicted as a solid block in FIG. 3B, the coil structure 303 can have a filling ratio (e.g., a proportion of the coil structure that is occupied by a conductive material) that is less than 100%, as illustrated in FIG. 3A.

FIG. 3C illustrates additional examples of a coil structure of a transmission line 304. In some implementations, the coil structure includes at least one of a planar square spiral coil 324, a planar rectangular spiral coil, a planar hexagonal spiral coil 322, a planar octagonal spiral coil 320, or a planar circular spiral coil 326. Without being limited to any particular theory, planar hexagonal or octagonal spiral coil 320, 322 may offer better space utilization compared to circular designs, the planar square or rectangular spiral coil 324 may provide a simple fabrication process, while the planar circular spiral coil 326 may offer better performance by reducing resistance and loss due to sharp corners. It is understood that the examples in FIGS. 3A and 3C are for illustration purpose and are not intended to be construed in a limiting sense. Other coil shape can also be employed for the coil structure.

FIG. 4A illustrates an example of an equivalent circuit 400 for a transmission line. The transmission line can be any implementation of the transmission line encompassed in the disclosure, e.g., the transmission line 104 of FIGS. 1A-1C, and/or the transmission line 304 of FIGS. 3A-3C. For illustration purpose, the transmission line 304 of FIGS. 3A-3B and the solder pad 302 of FIGS. 3A-3B will be used as an example in the subsequent discussions for simplicity. It is understood that the equivalent circuit 400 in FIG. 4A can be simplified and not intended to be construed in a limiting sense. Other equivalent circuits are also possible for a transmission line 304.

Without being limited to any particular theory, when high-speed signals are transmitted through a transmission line 304, a segment of the transmission line 304 can be approximated as an LC series-parallel circuits, as shown in FIG. 4A. The impedance of a segment of the transmission line 304 can be approximately calculated using the following formula:

$${Z}_{0} = \sqrt{\frac{L}{C}} \qquad ( Equation 1 )$$

where C is a capacitance per unit length (or unit area), L is an inductance L per unit length (or unit area), and Z₀, is an impedance.

As the solder pad 302 is coupled to the coil structure 303 of the transmission line 304, the combined structure of the solder pad 302 and the coil structure 303 can be considered as a segment of the transmission line 304. In some examples, the solder pad 302 can have a greater capacitance

C compared to other segments of the transmission line 304 (e.g., the routing structure 305 of FIG. 3A). Without the coil structure 303 to enhance the inductance L, the overall impedance for the combined structure can be smaller than other segments of the transmission line 304, causing impedance mismatch. Impedance mismatch may lead to signal reflections, thereby degrading the integrity of high-speed signals and causing high signal loss and power dissipation. In contrast, with the coil structure 303 to increase the inductance L of the combined structure, the overall impedance of the combined structure can be adjusted to match the impedance of other segments of the transmission line 304, thereby reducing signal loss and improving signal integrity.

In some implementations, an impedance of a combination of the coil structure 303 and the solder pad 302 is substantially equal to an impedance of the routing structure 305. In some examples, the coil structure 303 can be designed based on a target impedance of the combined structure. The target impedance for the combined structure can be the characteristic impedance of the routing structure 305, source/load impedance, or any other impedance for the purpose of impedance matching. Examples of target impedance include 50 ohms, 75 ohms, 100 ohms, or any other suitable values. Based on the target impedance, geometric parameters of the coil structure 303 (e.g., an inner diameter, an outer diameter, a width of the coil structure 303, a number of turns, and/or a filling ratio of the coil structure 303) can be determined by the following steps:

Step 1: determine, using Equation 1, the required inductance Lc of the coil structure 303 based on the capacitance Cs of the solder pad 302 and the target impedance ZT for the combined structure of the solder pad 302 and the coil structure 303; and

Step 2: determine the geometric parameters of the coil structure 303 based on at least the required inductance Lc of the coil structure 303 that is obtained from the step 1. Different coil shapes may have different correlations between the inductance and the geometric parameters. In some examples, the inductance of a single-layer circular spiral coil structure (e.g., 326 of FIG. 3C) can be correlated to its geometric parameters based on modified Harold A. Wheeler formula:

$$L = 31.33 {μ}_{0} \frac{{n}^{2} {a}^{2}}{8 a + 11 c} \qquad ( Equation 2 )$$

where L is an inductance in Henries, μ₀ is vacuum permeability (H/m), a is an average radius in meters:

$$a = \frac{{d}_{out} + {d}_{in}}{4} ,$$

where dᵢₙ is an inner diameter, dₒᵤₜ is an outer diameter, c is a width of coil in meters:

$$a = \frac{{d}_{out} - {d}_{in}}{2} ,$$

and n is a number of turns.

In some examples, the inductance of a single-layer square, hexagonal and octagonal spiral coils (e.g., 324, 322, 320 of FIG. 3C) can be correlated to its geometric parameters based on a modified Wheeler formula:

$$L = {K}_{1} {μ}_{0} \frac{{n}^{2} {d}_{avg}}{1 + {K}_{2} ρ} \qquad ( Equation 3 )$$

where L is the inductance in Henries, μ₀ is the vacuum permeability (H/m), n is a number of turns, d_{avg} is the average diameter in meters, K₁ and K₂ are the empirical dimensionless coefficients that can be dependent on the coil shape, and ρ is the filling ratio of the coil defined as

$$ρ = \frac{{d}_{out} - {d}_{in}}{{d}_{out} + {d}_{in}} ,$$

where dᵢₙ is an inner diameter, dₒᵤₜ is an outer diameter. FIG. 4B illustrates a table with example dimensionless coefficients used in Equation 3 for different shapes of the coil structure. For example, for a single-layer octagonal spiral coil, K₁ can be 2.25, and K2 can be 3.55.

It is to be noted that Equation 2 and 3 are not intended to be construed in limited sense, other formulas can be used to calculate the geometric parameters of the coil structure 303 based on the required inductance L_{c} of the coil structure 303 for the purpose of impedance matching along the transmission line 304.

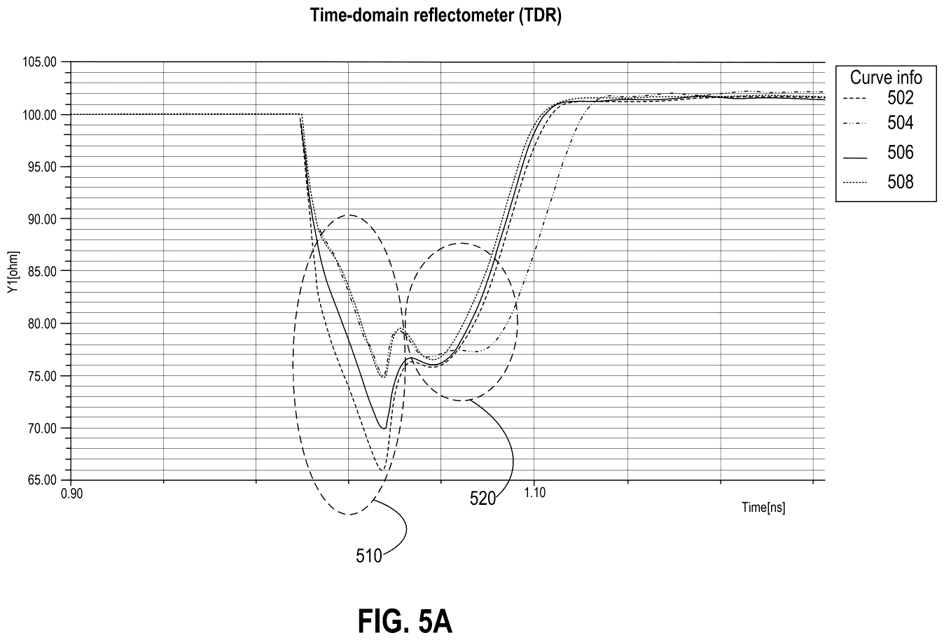

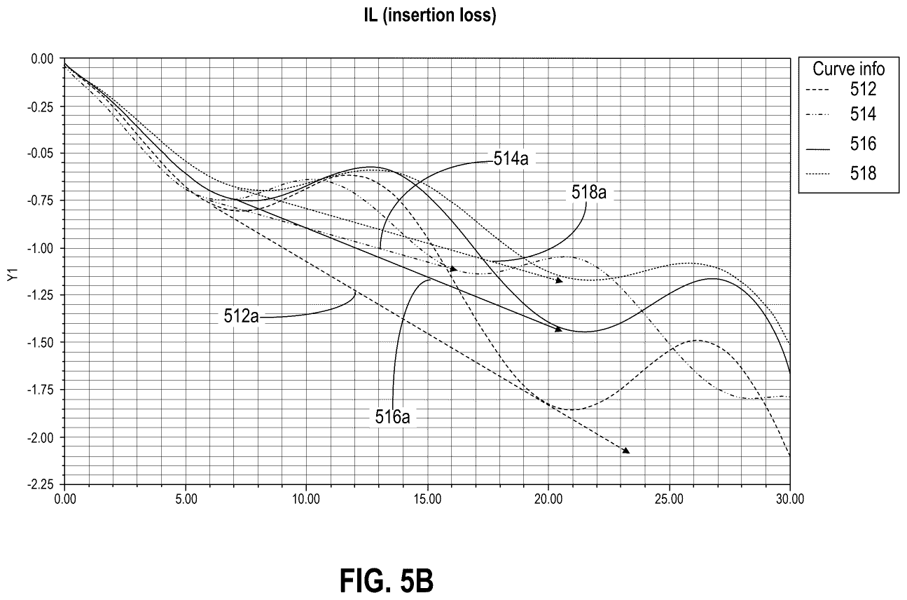

FIG. 5A illustrates an example of a time-domain reflectometer (TDR) figure associated with various configurations of transmission lines. FIG. 5B illustrates an example of an insertion loss figure corresponding to the transmission lines in FIG. 5A. Specifically, curves 502, 512 are corresponding to a reference transmission line #1 without a coil structure but with a routing structure of 5300 μm in length. Curves 504, 514 are corresponding to a transmission line #2 with a coil structure 303 adjacent to the solder pad 302 and with a routing structure 305 of 7000 μm in length, according to one or more implementations of the present disclosure. Curves 506, 516 are corresponding to a reference transmission line #3 without a coil structure but with a routing structure of 5300 μm in length. The reference transmission line #3 differs from the reference transmission line #1 in that in the reference transmission line #3, the space under the solder pad is empty. Curves 508, 518 are corresponding to a transmission line #4 with a coil structure 303 adjacent to the solder pad 302 and with a routing structure 305 of 5300 μm in length, according to one or more implementations of the present disclosure. The transmission line #4 differs from the transmission line #2 in the length of the routing structure.

Referring to FIG. 5A, in the coordinate system, the horizontal axis is time in ns, whereas the vertical axis represents the impedance in ohms. The time in the horizontal axis can correspond to the travel time of the signal as it propagates along the transmission line #1, #2, #3, #4 at a certain velocity. Therefore, the horizontal axis can indirectly represent different positions along the transmission line #1, #2, #3, #4, and the vertical axis can thus represent the impedance along the longitudinal length of the transmission line #1, #2, #3, #4. For example, for the transmission lines #2 and #4 according to one or more implementations of the present disclosure, the region 510 of curves 504, 508 can indicate the impedance of the combined structure of the coil structure 303 and the solder pad 302. For the reference transmission line #1 without a coil structure, the region 510 of curves 502 can indicate the impedance of the solder pad 302 and an end segment of the reference transmission line (e.g., an end segment 612 without a coil shape as illustrated in FIG. 6A). For the reference transmission line #3 without a coil structure, the region 510 of curves 506 can indicate the impedance of the solder pad 302 only. For all four transmission lines, the region 520 can refer to the impedance along other segments of the transmission lines. For example, the region 520 for transmission line #2 and #4 can correspond to the impedance of the routing structure 305 of the transmission line 304 of FIGS. 3A-3B, and/or of the routing structure 605 of the transmission line 604 of FIG. 6B. The region 520 for the reference transmission line #1 can be the routing structure 622 of FIG. 6A.

With continued reference to FIG. 5A, without a coil structure to compensate for inductance in the region 510, the reference transmission lines #1, #3 (corresponding to curves 502, 506) have a lower impedance, which is mismatched with other segments of the corresponding transmission lines (e.g., region 520). In contrast, with the coil structure 303 to compensate for inductance in the region 510 according to one or more implementations of the present disclosure, the impedance in region 510 can be increased, effectively reducing the impedance mismatch with other segments of the transmission line (e.g., region 520). As shown in FIG. 5A, the impedance difference between the region 510 and the region 520 for the transmission lines #2, #4 (corresponding to curves 504, 508) are significantly smaller than that for the reference transmission lines #1, #3 (corresponding to curves 502, 506). With improved impedance mismatch, the signal reflections along the transmission lines #2, #4 can be reduced, and signal quality can be improved.

Referring now to FIG. 5B, in the coordinate system depicted in FIG. 5B, the horizontal axis represents the frequencies of signals transmitted through the transmission lines, whereas the vertical axis represents the insertion loss of the signals. As shown in FIG. 5B, as frequency increases, the insertion loss may increase due to factors including resistive loss, skin effect, etc. As noted above, four insertion loss curves 512, 514, 516, 518 correspond to four different configurations of transmission lines. For each insertion loss curve 512, 514, 516, 518, the respective dashed line 512a, 514a, 516a, 518a connects the first and second resonance points of the insertion loss, and the slope of the dashed line can correspond to rate of change in the insertion loss. A steeper slop of the dashed line may indicate a more rapid insertion loss, while a shallower slope of the dashed line may indicate a more gradual change. As illustrated in FIG. 5B, the slopes for dashed lines 514a, 518a (corresponding to transmission lines #2, #4 of FIG. 5A that each includes a coil structure) are much shallower compared to those of the dashed lines 512a, 516a (corresponding to reference transmission lines #1, #3 of FIG. 5A that do not include a coil structure). This can indicate that the implementations of the present disclosure can have a lower insertion loss. Additionally, as illustrated in FIG. 5B, the improvement of the insertion loss can be more significant when the frequency is higher. Lower insertion loss can mean less signal attenuation, thereby providing improved transmission range and high-frequency performance.

FIG. 6A illustrates an example of a simulation result of impedance along a reference transmission line without a coil structure. The reference transmission line can be the reference transmission line #1 described above in reference to FIGS. 5A and 5B. FIG. 6B illustrates an example of a simulation result of impedance along a transmission line 604 with a coil structure 603 according to one or more implementations of the present disclosure. The transmission line 604 with the coil structure 603 can be any implementation of the transmission line encompassed in the disclosure, e.g., the transmission line 104 of FIGS. 1B-1C, the transmission line 304 of FIGS. 3A-3B, or the transmission lines #2, #4 described above in reference to FIGS. 5A and 5B. The coil structure 603 in FIG. 6B can have the same or similar coil shape as the coil structure 303 of FIG. 3A. Different shade in FIGS. 6A and 6B can represent different impedance, with a lighter shade indicating a lower impedance.

As illustrated in FIG. 6A, the impedance of the reference combined structure 620, which includes an end segment 612 (without a coil structure) of the reference transmission line #1 and a solder pad, can be lower than that of other segments of the reference transmission line #1, indicating a significant impedance mismatch. As noted above, the lower impedance of the reference combined structure 620 can be due to a larger capacitance of the solder pad.

In contrast, as illustrated in FIG. 6B, with a coil structure 603 to compensate for inductance, the impedance of the combined structure 610 that includes the coil structure 603 and a solder pad (e.g., 302 of FIG. 3B) can be substantially equal to the impedance of the routing structure 605. Therefore, the impedance can be more uniform along the transmission line 604 compared to the reference transmission line #1 in FIG. 6A. Therefore, the implementations of the present disclosure can greatly improve the impedance mismatch, thereby providing better signal integrity during transmission.

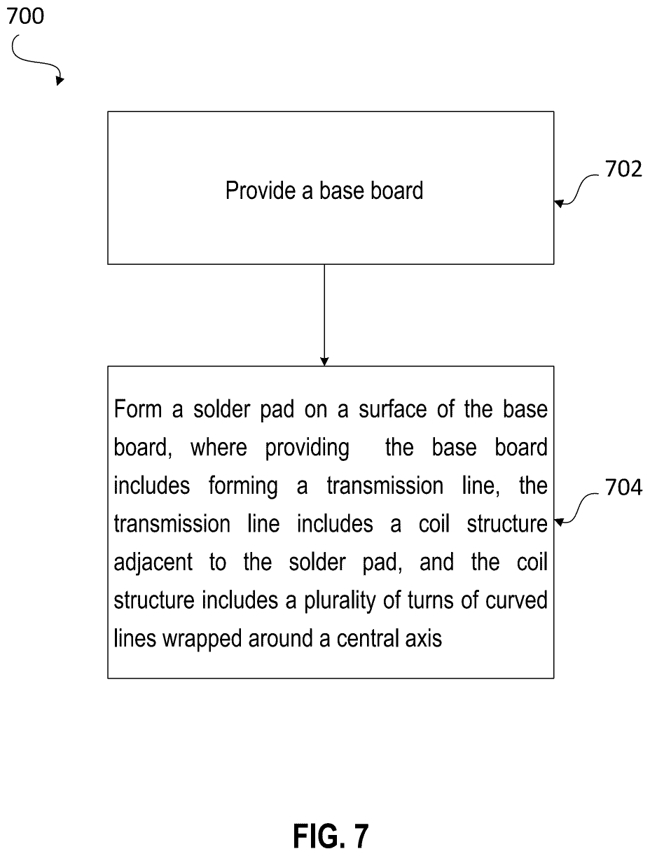

FIG. 7 illustrates a flow chart of a process of an example method 700 of forming a chip package. The chip package can be, e.g., the chip package 100 of FIGS. 1A-1C, the chip package 200 of FIGS. 2A-2B, or the chip package 300 of FIGS. 3A-3C.

At step 702, a base board is provided. The base board can be, e.g., the base board 110 of FIGS. 1A-1C, the base board 210 of FIGS. 2A-2B, or the base board 310 of FIGS. 3A-3B.

At step 704, a solder pad is formed at a surface of the base board. Providing the base board includes forming a transmission line, the transmission line includes a coil structure adjacent to the solder pad, and the coil structure includes a plurality of turns of curved lines wrapped around a central axis. The solder pad can be, e.g., the solder pad 102 of FIGS. 1A-1C, the solder pad 202 of FIGS. 2A-2B, or the solder pad 302 of FIGS. 3A-3B. The transmission line can be, e.g., the transmission line 104 of FIGS. 1A-1C, the transmission line 304 of FIGS. 3A-3C, the transmission lines #2, #4 described in reference to FIGS. 5A-5B, or the transmission line 604 of FIG. 6B. The coil structure can be, e.g., the coil structure 303 of FIGS. 3A and 3B, any one of spiral coils 320, 322, 324, 326 of FIG. 3C, any one of the coil structures of the transmission lines #2, #4 described in reference to FIGS. 5A-5B, or the coil structure 603 of FIG. 6B.

In some implementations, the method includes determining at least one of a length of the coil structure or a number of turns of the plurality of turns of curved lines of the coil structure based on at least a target impedance and a capacitance of the solder pad, as described above in reference to FIGS. 4A-4B.

In some implementations, the transmission line includes a routing structure extending from the coil structure. Forming the transmission line includes: forming the transmission line such that an impedance of a combination of the coil structure and the solder pad is substantially equal to an impedance of the routing structure, as described above in reference to FIGS. 4A-6B. The routing structure can be, e.g., the routing structure 305 of FIG. 3A or the routing structure 605 of FIG. 6B.

In some implementations, the coil structure of the transmission line at least partially overlaps with the solder pad, e.g., as illustrated in FIGS. 1A-3B.

FIG. 8 illustrates a block diagram of a system 800 having one or more semiconductor devices (e.g., memory devices), according to one or more implementations of the present disclosure. The system 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, the system 800 can include a host device 808 and a memory system 802 having one or more 3D memory devices 804 and a memory controller 806. Host device 808 can include a processor of an electronic device, such as a central processing unit (CPU), or a system-on-chip (SoC), such as an application processor (AP). Host device 808 can be configured to send or receive data to or from the one or more 3D memory devices 804.

In some implementations, a 3D memory device 804 can be memory structure 120 in the memory device or the chip package 100 of FIGS. 1A-1C, memory structure in the chip package 200 of FIGS. 2A-2B, or memory structure in the chip package 300 of FIGS. 3A-3C.

In some implementations, a memory system 802 can be any 3D memory device disclosed herein, such as the memory device or the chip package 100 of FIGS. 1A-1C, the chip package 200 of FIGS. 2A-2B, or the chip package 300 of FIGS. 3A-3C. As noted above, the memory system 802 can be a UFS.

In some implementations, a 3D memory device 804 includes a NAND Flash memory. Memory controller 806 (a.k.a., a controller circuit) is coupled to 3D memory device 804 and host device 808. Consistent with implementations of the present disclosure, 3D memory device 804 can include a plurality of conductive interconnections through a cover layer that are in contact with conductive pads in a conductive pad layer, and memory controller 806 can be coupled to 3D memory device 804 through at least one of the plurality of conductive interconnections. Memory controller 806 is configured to control 3D memory device 804. For example, memory controller 806 may be configured to operate a plurality of channel structures via word lines. Memory controller 806 can manage data stored in 3D memory device 804 and communicate with host device 808.

In some implementations, memory controller 806 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program (or write) operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Any other suitable functions may be performed by memory controller 806 as well, for example, formatting 3D memory device 804.

Memory controller 806 can communicate with an external device (e.g., host device 808) according to a particular communication protocol. For example, memory controller 806 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 8, memory controller 806 and a single 3D memory device 804 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some embodiments,” “some implementations,” “one implementation,” “an implementation,” “an example implementation,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

As used in this disclosure, the term “substantially” or “substantial” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

As used herein, the term “surrounded by” refers to at least partially surrounded by. For example, A is surrounded by B can refer to that A is at least partially surrounded by B.

As used herein, the term “and/or” as used herein refers to and encompasses any and all possible combinations of one or more of the associated listed terms. For example, the term “A and/or B” means that either option A, option B, or both options A and B are possible, where A and B may be singular or plural.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above- described exemplary implementations, but should be defined only in accordance with the following claims and their equivalents.

What is claimed is:

1. A chip package, comprising:
a base board; and
a solder pad positioned at a surface of the base board, wherein the base board comprises a transmission line coupled to the solder pad, the transmission line comprises a coil structure positioned adjacent to the solder pad, and the coil structure comprises a plurality of turns of curved lines wrapped around a central axis.

2. The chip package of claim 1, wherein the coil structure of the transmission line at least partially overlaps with the solder pad.

3. The chip package of claim 1, wherein the coil structure comprises a planar spiral coil.

4. The chip package of claim 3, wherein the planar spiral coil comprises at least one of a planar square spiral coil, a planar rectangular spiral coil, a planar hexagonal spiral coil, or a planar octagonal spiral coil.

5. The chip package of claim 1, wherein the transmission line comprises a routing structure extending from the coil structure, and an impedance of a combination of the coil structure and the solder pad is substantially equal to an impedance of the routing structure.

6. The chip package of claim 1, wherein the solder pad has a capacitance C, the coil structure has an inductance L, and the capacitance C of the solder pad is correlated with the inductance L of the coil structure, satisfying
$${Z}_{0} = \sqrt{\frac{L}{C}} ,$$
where Z₀ is a target impedance.

7. The chip package of claim 1, wherein the coil structure has a uniform pitch between adjacent turns of the plurality of turns of curved lines.

8. The chip package of claim 1, wherein each curved line of the plurality of turns of curved lines has a different perimeter.

9. The chip package of claim 1, wherein the transmission line is configured to transmit a serializer-deserializer (SERDES) signal.

10. The chip package of claim 1, wherein the chip package comprises a ball grid array (BGA) package including the base board, and the solder pad is connected to a solder ball.

11. A memory device, comprising:
a base board;
a solder pad positioned on the base board,
wherein the base board comprises:
a transmission line coupled to the solder pad, the transmission line comprises a coil structure positioned adjacent to the solder pad, and the coil structure comprises a plurality of turns of curved lines wrapped around a central axis; and
a conductive line;
a memory structure comprising a plurality of memory cells and positioned on the base board; and
a control structure comprising a control circuit and positioned on the base board,
wherein the memory structure is coupled to the control structure through the conductive line of the base board.

12. The memory device of claim 11, wherein the transmission line has a first end coupled to the control structure and a second end coupled to the solder pad, the second end comprising the coil structure.

13. The memory device of claim 11, comprising:
a molding encapsulant configured to encapsulate at least the memory structure and the control structure on the base board.

14. The memory device of claim 11, wherein the coil structure of the transmission line at least partially overlaps with the solder pad.

15. The memory device of claim 11, wherein the transmission line comprises a routing structure extending from the coil structure, and an impedance of a combination of the coil structure and the solder pad is substantially equal to an impedance of the routing structure.

16. The memory device of claim 11, wherein the solder pad has a capacitance C, the coil structure has an inductance L, and the capacitance C of the solder pad is correlated with the inductance L of the coil structure, satisfying
$${Z}_{0} = \sqrt{\frac{L}{C}} ,$$
where Z₀ is a target impedance.

17. A method, comprising:
providing a base board; and
forming a solder pad at a surface of the base board,
wherein providing the base board comprises forming a transmission line, the transmission line comprises a coil structure adjacent to the solder pad, and the coil structure comprises a plurality of turns of curved lines wrapped around a central axis.

18. The method of claim 17, comprising:
determining at least one of a length of the coil structure or a number of turns of the plurality of turns of curved lines of the coil structure based on at least a target impedance and a capacitance of the solder pad.

19. The method of claim 17,
wherein the transmission line comprises a routing structure extending from the coil structure, and
wherein forming the transmission line comprises: forming the transmission line such that an impedance of a combination of the coil structure and the solder pad is substantially equal to an impedance of the routing structure.

20. The method of claim 17, wherein the coil structure of the transmission line at least partially overlaps with the solder pad.
